(19) United States
(12) Patent Application Publication
(10) Pub. No.: US 2011/0024169 A1
(43) Pub. Date: Feb. 3, 2011

(54) SILICON NANOWIRE ARRAYS ON AN ORGANIC CONDUCTOR

(76) Inventors: Brent A. Buchine, Watertown, MA (US); Jeff Miller, Cambridge, MA (US); Marcie R. Black, Lincoln, MA (US); Faris Modawar, Georgetown, TX (US)

Correspondence Address: IRELL & MANELLA LLP, 1800 AVENUE OF THE STARS, SUITE 900, LOS ANGELES, CA, 90067, US

(21) Appl. No.: 12/845,557

(22) Filed: Jul. 28, 2010

Related U.S. Application Data
(60) Provisional application No. 61/229,058, filed on Jul. 28, 2009.

(51) Int. Cl. H05K 1/00; C23F 1/24; B82Y 30/00

(52) U.S. Cl. 174/258; 174/250; 216/13; 977/762; 977/932

(57) ABSTRACT

In an aspect of the invention, a process to make a nanowire array is provided. In the process, silicon is deposited onto a conductive substrate comprising an organic material and optionally a conductive layer, thus forming a silicon-containing layer. Nanoparticles are deposited on top of the silicon-containing layer. Metal is deposited on top of the nanoparticles and silicon in such a way that the metal is present and touches silicon where etching is desired and is blocked from touching silicon or not present elsewhere. The metallized substrate is contacted with an etchant aqueous solution comprising about 2 to about 49 weight percent HF and an oxidizing agent.

### CROSS-REFERENCE TO RELATED APPLICATIONS

This application claims the benefit of U.S. Provisional Application Ser. No. 61/229,058, filed Jul. 28, 2009.

### BACKGROUND OF THE INVENTION

The requirement for high power and high energy density in lithium ion batteries has fueled the search for improved anodes and cathodes. Silicon has been proposed as a desirable anode material since it has the highest known lithium ion storage capacity of all materials: approximately 11 times that of graphite. However, silicon expands to four times its volume when fully loaded with lithium, leading to the pulverization and rapid fade of the material in less than 10 cycles.

Nanostructuring has been suggested as an approach to avoid rapid fade while still benefiting from the high storage capacity of silicon. The idea is to add nano-scale voids in the material, giving the silicon room to expand and contract, thereby reducing the stresses in the material, which lead to degradation of the device. Silicon nanowires are a particularly good choice for battery anodes. In addition to providing plenty of space between the wires to allow for expansion, nanowires are also known to exhibit greater elasticity when compared to their bulk counterpart. In addition, nanowires have a high surface area to volume ratio, which may improve the rate of lithium charge and discharge, thus increasing the overall power of the battery. Finally, nanowires provide a direct path for low-resistance charge transport to the contact when compared to other nanomaterials. Charge transport in nanowires can be enhanced further if the wires are aligned in vertical arrays as opposed to random “spaghetti-like” arrangements.

Recently, silicon nanowires made by the vapor-liquid-solid (VLS) technique were measured with a very high lithium capacity (˜3000 mAh/g) and were cycled 20 times, which is a large improvement over bulk silicon. See reference (b). Silicon nanowires with an amorphous shell and a crystalline core have demonstrated an 85% discharge capacity retention for over 100 cycles, although at a lower capacity of ˜1060 mAh/g—still a significant improvement over graphite. See reference (c). The improved durability of these core/shell nanowires may be in part attributable to the amorphous silicon: since amorphous silicon lacks long-range structural order, it may be more resilient to pulverization and may survive more cycles than crystalline silicon.

Vertically aligned, amorphous silicon nanowire arrays may be a desirable anode structure for lithium ion batteries. However, this combination of properties is difficult to achieve inexpensively using standard nano-fabrication techniques.

### SUMMARY OF THE INVENTION

In an aspect of the invention, an array of aligned silicon nanowires is provided, which is coupled to a conducting substrate comprising an organic material, wherein the majority of the nanowires are at least approximately perpendicular to the substrate.

In an aspect of the invention, a process to make a nanowire array is provided. In the process, silicon is deposited onto a conductive substrate comprising an organic material and optionally a conductive layer, thus forming a silicon-containing layer. Nanoparticles are deposited on top of the silicon-containing layer. Metal is deposited on top of the nanoparticles and silicon in such a way that the metal is present and touches silicon where etching is desired and is blocked from touching silicon or not present elsewhere. The metallized substrate is contacted with an etchant aqueous solution comprising about 2 to about 49 weight percent HF and an oxidizing agent.

### BRIEF DESCRIPTION OF THE FIGURES

FIG. 1 depicts an array of silicon nanowires made via processing techniques developed by the inventors.

FIG. 2 depicts an SEM of silicon nanowires after many cycles of lithium charge and discharge.

FIG. 3 depicts cycling data of a cell built with silicon nanowire arrays cycled at 500 mA charge and 250 mA discharge.

FIG. 4 schematically depicts silicon nanowires on an organic conductor.

### DETAILED DESCRIPTION OF THE INVENTION

Before describing the present invention in detail, it is to be understood that this invention is not limited to specific solvents, materials, or device structures, as such may vary. It is also to be understood that the terminology used herein is for the purpose of describing particular embodiments only, and is not intended to be limiting.

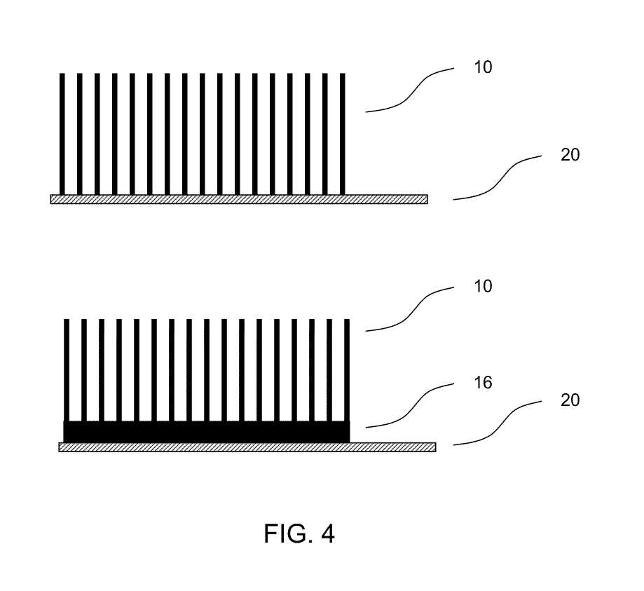

A class of processes has been discovered which makes use of the high lithium ion capacity of silicon, avoids the pulverization that commonly occurs for silicon anodes, and allows for good adhesion of the lithium absorbing material with the conductor and substrate of the anode. It becomes possible to manufacture a device comprising an organic conductor with an array of silicon nanowires attached, as depicted schematically in FIG. 4. In the figure, one sees nanowires 10 and an organic conductor 20. Optionally the nanowires have a silicon base 16. The silicon nanowires fabricated by the processes of the invention can be amorphous silicon, which is thought to improve fade in the devices.

In addition to having a high lithium ion absorption capacity, an anode for a lithium ion battery should comprise a substrate to connect the nanowires to each other and the external contact of the battery. The substrate may provide both structural support and electrical conduction and ideally is as light as possible. It is also desirable that the substrate be elastic enough to be durable throughout many expansion and compression cycles.

The substrate for a lithium ion battery may comprise an organic conductor. Such conductors can be chosen to be very elastic, inexpensive, and lightweight. When using an organic conductor, it is preferable to use a process for manufacturing the battery which is compatible with the material and in particular maintains temperatures within ranges which do not damage or destroy the organic conductor.

In an aspect of the invention, a process is provided for making silicon nanowires on a conductive substrate. In this process, one deposits silicon onto a conducting film comprising an organic material and deposits a metal film onto the silicon. One submerges the metallized substrate into an etchant aqueous solution comprising about 4 to about 49 weight percent HF and an oxidizing agent.

In one embodiment of the process, the organic material in the substrate itself is conductive, for example a polymer such as polyaniline. Other conductive polymers include poly(acetylene)s, poly(pyrrole)s, poly(thiophene)s, poly(aniline)s, poly(fluorene)s, poly(3-alkylthiophene)s, polytetrathiafulvalenes, polynaphthalenes, poly(p-phenylene sulfide), and poly(para-phenylene vinylene)s. The conductivity of the organic material may lie in the range of about 0.1-100 S/cm or about 1-10 S/cm. When the organic material is conductive, the silicon nanowires may be deposited directly on top of that organic material. With this arrangement, electrons may be harvested through the substrate itself.

A second embodiment is to use a non-conductive flexible substrate such as an insulating polymer like polyimide and deposit a conductive layer on top prior to depositing silicon and fabricating the nanowire arrays. In this situation, the organic substrate would not contribute to the electrical properties of the cell. However, a conductive film sandwiched between the nanowire arrays and polymer support would serve as the contact point for harvesting electrons. A device designed around either of these approaches could be lighter weight and have a certain degree of flexibility that might be useful in a host of portable applications.

It is helpful in this embodiment to match the insulating polymer's elastic properties and coefficient of thermal expansion to those of the nanowires, for example via additives. There has been much research on control of the coefficient of thermal expansion in polymers. Certain polyimide derivatives, like Kapton (DuPont) and Novastrat (SRS Technologies, Huntsville, Ala.), can have their elastic properties and expansion coefficients tuned to more directly match the properties of the silicon nanowires. It may be desirable, for example, that the coefficient of thermal expansion of the insulating polymer be no greater than about 2 times, about 1.5 times, or about 1.25 times that of the silicon nanowires.

An exemplary process is as follows:

First a conductive polymer substrate is prepared. A thin 100 nm titanium film is sputtered onto a 5 mm Kapton sheet at 4 mTorr, 200 W RF using an AJA International sputtering chamber. A thin layer of Si (50 nm) is deposited on top in a subsequent sputtering step to cap the titanium and prevent oxidations. Once the substrate is removed from the sputtering chamber, it is placed inside an STS PECVD tool in order to deposit a thick layer of a-Si on top of the conductive substrate. Eight microns of material are deposited at a rate of approximately 70 nm/min. The process parameters are as follows: SiH₄ Flow-50 SCCM; Ar Flow-600 SCCM; Pressure—1000 mTorr; Power; 52 W HF; Platen temperature: 200° C.; Lid temperature: 200° C. After the deposition is complete, the substrate is treated with a Piranha solution made up of 3 parts 96% H₂SO₄ and 1 part 30 wt % H₂O₂. This is done by first mixing the solution in a separate glass beaker and swabbing the piranha onto the surface of the silicon without allowing the solution to interact with the underlying polymer. This procedure prevents the piranha solution from attacking the underlying substrate while still producing a hydrophilic silicon surface. The substrate is then sprayed with flowing deionized water for 3 minutes to remove any residual acids and blown dry with nitrogen gas.

Instead of a Kapton sheet with a thin film, polyaniline can be used as an alternative substrate. Polyaniline is prepared into a thin substrate as described in J. Stejskal, Pure Appl. Chem., Vol. 74, No. 5, pp. 857-867 (2002). Polyaniline being an organic conductor, metal need not be sputtered prior to the CVD of a-Si. Once the polyaniline substrate is pressed and ready, the material is placed directly into the STS PECVD chamber and coated with eight microns of a-Si using the same process parameters listed above. The piranha solution is prepared and swabbed in the same way as previously described.

A colloidal suspension of 10 nm iron oxide nanoparticles in chloroform is made by diluting product #SOR-10-0050 from Ocean Nanotech to a concentration of 1 mg/mL. The nanoparticle solutions are then diluted with ethyl lactate in a 2:1 ethyl lactate to nanoparticle solution ratio. The solution is then spun onto the silicon chip by ramping at 500 RPM/s to a 500 RPM spread step followed by a ramp at 1000 RPM/s to 4000 RPM for 40 seconds. After spin coating, the substrate is cleaned using a UV-Ozone treatment for six minutes at 60 C prior to metal deposition.

Silver (Ag) is deposited via physical vapor deposition inside a sputtered, thermal evaporator or e-beam evaporator to a thickness of 130 Å. A continuous film with no breaks, cracks, or holes results.

Once the chip is coated with the appropriate film of Ag, the HF solution is seasoned before commencing the etching reaction. The concentration of HF can vary from full strength (about 49 wt %) all the way down to very nominal concentrations. Concentrations as low as 2 wt % and below may be used. For example, a solution of 4 wt % HF may be used. As HF concentration is altered, the optimal film thickness may need to be varied. For 130 Å of Ag, a good concentration is ˜4 wt % HF diluted in DI H₂O.

O₂ gas is flowed into the bath to create a vigorous bubbling for a period of 10 minutes. Once the bath is seasoned, the samples are submerged for ˜20-30 minutes depending on the desired length of the nanowires. Note that the flow rate of O₂ affects the etch rate. To etch 8 microns deep, a control sample should be etched first to determine the appropriate etch rate to achieve full length nanowires without over-etching the sample. At the completion of the etch, the samples are removed and put into a dump-tank of flowing DI water and blown dry with N₂. At this point the remaining Ag on the surface can be removed with a silver etchant, for example the Ag etchant supplied by Transene Corporation.

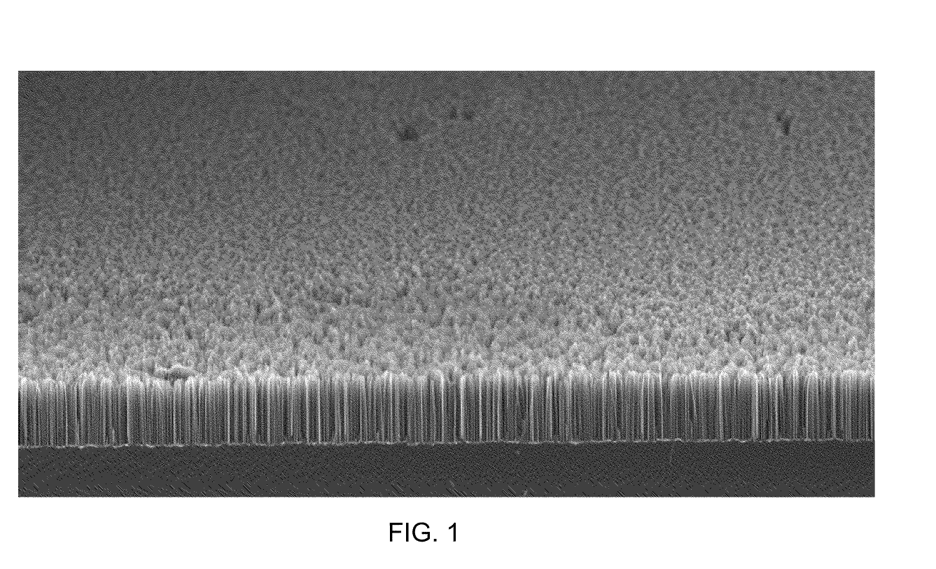

An example of a nanowire array fabricated with our process is shown in FIG. 1.

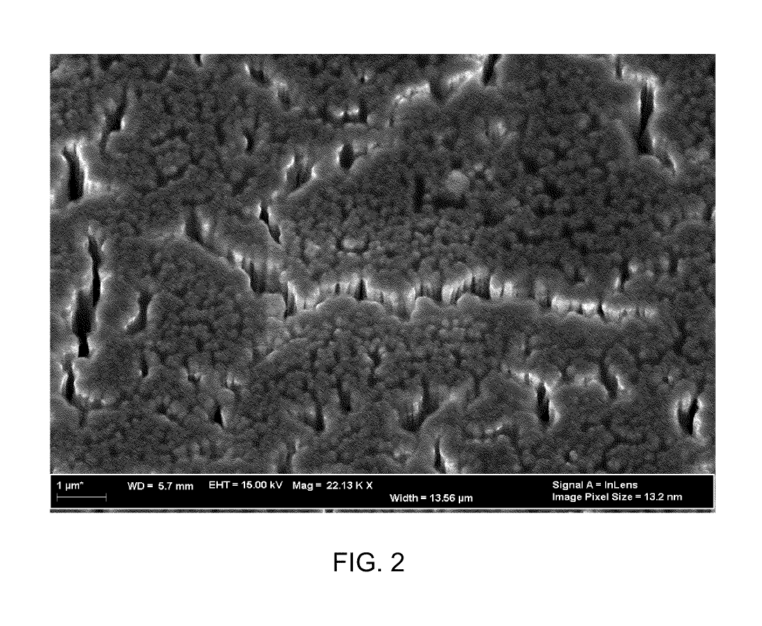

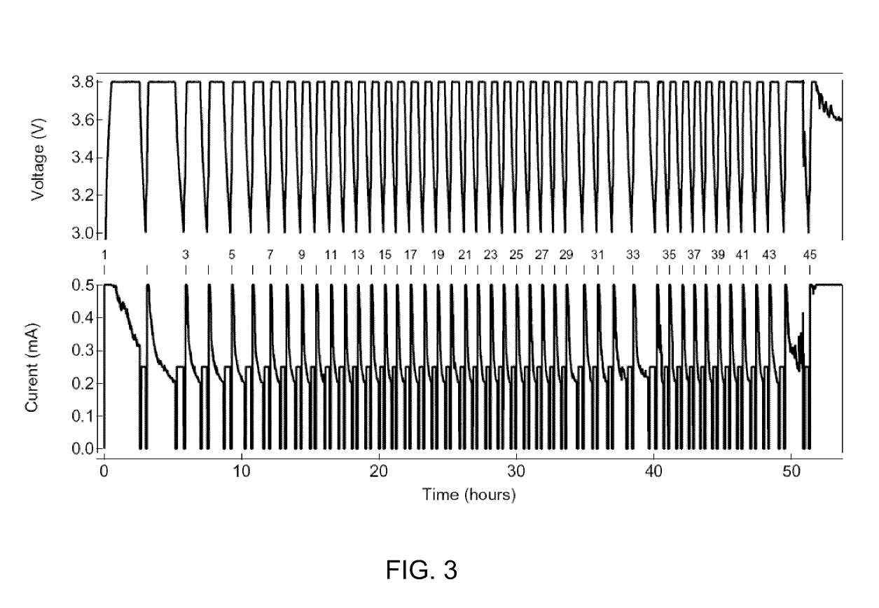

The inventors built 3 cm² amorphous silicon nanowire arrays on a thin layer of titanium (for electrical contact) on a ceramic substrate. These anodes were assembled into a cell opposite a LiMO₂ (M=Ni, Mn, and/or Co) cathode. Gold was sputtered onto the ends of the first sample to provide more assured contact through an alligator clip. The sample was introduced into the glove box and assembled into a cell utilizing a small piece of lithium foil. This piece of lithium was approximately 0.5 cm² in area and was placed on a piece of Celgard 2325 (obtained from Celgard, LLC of Charlotte, N.C.) separator material with the sample on the opposite side. Liquid electrolyte was applied to the separator and a spring clip was used to secure the three layers together. The samples remained in the glove box during all testing. Alligator clips were attached to the lithium foil (negative terminal) and the Gold contact of the sample (positive terminal). These lead wires pass out of the glove box and extend to a Maccor 128 channel testing center. The cells showed high lithium absorption capacity, greater than 1300 mAh/g. After cycling 70 times, the nanowires showed no evidence of pulverization, which is a significant improvement over bulk silicon and other silicon nanowire technologies, see FIG. 2. FIG. 3 is an example of cycling data for a cell built with silicon nanowire arrays cycled at 500 μA charge and 250 μA discharge.

The following references are of interest in relation to this application: (a) Uday Kasavajjula, Chunsheng Wang, A. John Appleby, Journal of Power Sources 163 (2007) 1003-1039, (b) Candace K. Chan, Hailin Peng, Gao Liu, Kevin McIlwrath, Xiao Feng Zhang, Robert A. Huggins, and Yi Cui, Nature Nanotechnology 3 (January 2008) 31-35, including online supplementary information; (c) Li-Feng Cui, Riccardo Ruffo, Candace K. Chan, Haillin Peng, and Yi Cui, Nano Letters 9 (1) (2009) 491-495, (d) T. L Kulova, A. M. Skundin, Yu. V. Pleskov, O. I. Kon'kov, E. I. Terukov, and I. N. Trapeznikova, Chem. Biochem. Eng. Q. 21 (4) (2007) 83-92, (e) Candace K. Chan, Riccardo Ruffo, Seung Sae Hong, Robert A. Huggins, Yi Chui, Journal of Power Sources 189 (2009) 34-39; (f) U.S. Provisional Patent Application Ser. No. 61/114,896 entitled “Solar cells where a nanowire array makes up part of the n or p type region,” filed Nov. 14, 2008; (g) U.S. Provisional Patent Application Ser. No. 61/141,082, entitled “Process for Fabricating Nanowire Arrays,” filed Dec. 29, 2008; (h) U.S. Provisional Patent Application Ser. No. 61/142,608, entitled “Process for Structuring Silicon,” filed Jan. 5, 2009; (i) Sami Franssila, Introduction to Microfabrication (John Wiley & Sons, 2004); (j) U.S. Published Patent Application No. 2006/0207647 filed Mar. 16, 2005; (k) Jeffrey L. Gray, “The Physics of the Solar Cell,” in Handbook of Photovoltaic Science and Engineering ch. 3 (A. Luque & S. Hegedus eds. 2003).

It is to be understood that while the invention has been described in conjunction with the preferred specific embodiments thereof, the foregoing description is intended to illustrate and not limit the scope of the invention. Other aspects, advantages, and modifications within the scope of the invention will be apparent to those skilled in the art to which the invention pertains.

All patents, patent applications, and publications mentioned herein are hereby incorporated by reference in their entireties. However, where a patent, patent application, or publication containing express definitions is incorporated by reference, those express definitions should be understood to apply to the incorporated patent, patent application, or publication in which they are found, and not to the remainder of the text of this application, in particular the claims of this application.

1. An array of aligned silicon nanowires coupled to a conducting substrate comprising an organic material, wherein the majority of the nanowires are at least approximately perpendicular to the substrate.

2. A lithium ion absorbing material comprising silicon nanowires coupled to a substrate comprising an organic material.

3. An array as described in claim 1, wherein the array comprises amorphous silicon.

4. An array as described in claim 1, wherein the array comprises micro, poly, or nano silicon.

5. An array as described in claim 1, wherein the majority of the nanowires have diameters below 150 nm.

6. An array as described in claim 1, wherein the majority of the nanowires have diameters of no more than about 50 nm.

7. An array as described in claim 1, wherein the majority of the nanowires have diameters below 25 nm.

8. An array as described in claim 1, wherein the wires are made by metal enhanced etching of silicon.

9. An array as described in claim 1, wherein the substrate comprises polyaniline or polyimide.

10. An array as described in claim 1, wherein the conducting substrate comprises a non-conducting organic material and a layer of conductive material on top of the non-conducting organic material.

11. A process to make a nanowire array comprising the steps of:
(a) depositing silicon onto a conducting substrate comprising an organic material and optionally a conductive layer, thus forming a silicon-containing layer,
(b) depositing nanoparticles on the silicon-containing layer,
(c) depositing metal on top of the nanoparticles and silicon in such a way that the metal is present and touches silicon where etching is desired and is blocked from touching silicon or not present elsewhere, and
(d) contacting the metallized substrate with an etchant aqueous solution comprising about 2 to about 49 weight percent HF and an oxidizing agent.

12. A process as described in claim 11, wherein the oxidizing agent is oxygen gas bubbled through the etchant aqueous solution.

13. A process as described in claim 11, wherein the metal deposited and patterned in step (c) is silver.

14. A process as described in claim 13, wherein the silver is less than about 50 nm thick.

15. A process as described in claim 13, wherein the silver is between 11 and 18 nm thick.

16. A process as described in claim 11, wherein the result of steps (a)-(d) is a nanowire array where the average nanowire diameter is less than about 100 nm.

17. A process as described in claim 16, wherein the result of steps (a)-(d) is a nanowire array where the nanowire diameter is less than about 50 nm.

18. A process as described in claim 11, wherein the silicon on top of the organic substrate prior to deposition of the metal comprises polysilicon, nanosilicon, amorphous silicon, or microcrystalline silicon.

19. A process as described in claim 1 wherein the result of steps (a)-(d) is further processed to produce an anode for a lithium ion battery.

20. A process as described in claim 11, further comprising the step of employing the pattern created by steps (a)-(d) as a lithium-absorbing component of a lithium ion battery.

21. A device as described in claim 1, wherein the device is used in a photovoltaic cell.

22. A device as described in claim 1, wherein the device is used in a lithium ion battery.
